(19) United States
(12) Patent Application Publication
(10) Pub. No.: US 2019/0267531 A1
(43) Pub. Date: Aug. 29, 2019

(54) THERMOELECTRIC CONVERSION DEVICE

(71) Applicant: TDK CORPORATION, Tokyo (JP)

(72) Inventors: Makoto SHIBATA, Tokyo (JP); Kazuya MAEKAWA, Tokyo (JP); Takashi ASATANI, Tokyo (JP)

(73) Assignee: TDK CORPORATION, Tokyo (JP)

(21) Appl. No.: 16/334,929

(22) PCT Filed: Jul. 31, 2017
(86) PCT No.: PCT/JP2017/027634

§ 371 Date: Mar. 20, 2019

(30) Foreign Application Priority Data
Sep. 28, 2016 (JP) 2016-189517
Nov. 15, 2016 (JP) 2016-222296

(51) Int. Cl. H01L 35/30; H01L 35/32

(52) U.S. Cl. CPC H01L 35/30; H01L 35/32

(57) ABSTRACT

There is provided a thermoelectric conversion device comprising a substrate including a first surface and a second surface which are opposite to each other in a thickness direction, at least one thermoelectric conversion film disposed on the first surface, and a first heat transfer part disposed on a second surface side. The substrate is joined to the first heat transfer part in a movable state with respect to the first heat transfer part.

### TECHNICAL FIELD

The present disclosure relates to the technical field of thermoelectric conversion devices having thermoelectric characteristics.

Priority is claimed on Japanese Patent Application No. 2016-189517, filed Sep. 28, 2016, and Japanese Patent Application No. 2016-222296, filed Nov. 15, 2016, the content of which is incorporated herein by reference.

### BACKGROUND ART

Recently, from the viewpoints of saving energy, use of unused heat that is lost has attracted attention, and particularly, research has been actively conducted on thermoelectric conversion of waste heat in an internal combustion engine or a combustion apparatus. In the research on the thermoelectric conversion devices, a BiTe-based material having high performance in the vicinity of a room temperature has been mainstream, but the BiTe-based material is tending to deviate from the mainstream of research in consideration of a limit of thermoelectric conversion efficiency as a material system in addition to a problem of toxicity and an increase in a material cost. Accordingly, the aim of the research has transitioned to improving the thermoelectric conversion efficiency by lowering heat conductivity with a quantum structure by using a multi-layer film or a nano-composite combination film and the like instead of the BiTe-based material.

For example, Patent Literature 1 describes a thermoelectric conversion module (thermoelectric conversion device) in which a first heat transfer part is disposed on a first surface side of a substrate on which a thermoelectric conversion film is formed, and a second heat transfer part is disposed on a second surface side opposite to the first surface of the substrate. A protrusion is provided on one surface of each of the first heat transfer part and the second heat transfer part.

The protrusion of the first heat transfer part is in contact with a high-temperature side electrode that is formed at an end of the thermoelectric conversion film. The protrusion of the second heat transfer part is in contact with the second surface of the substrate at a position corresponding to a low-temperature side electrode that is formed on an opposite end of the thermoelectric conversion film in a thickness direction of the substrate.

### CITATION LIST

### Patent Literature

International Publication No. 2011/065185

### SUMMARY

### Technical Problem

In Patent Literature 1, heat that is used in thermoelectric conversion is transferred from the first heat transfer part to the thermoelectric conversion film through the protrusion of the first heat transfer part and the high-temperature side electrode, and an end of the thermoelectric conversion film formed on the first surface of the substrate. In addition, the heat is transferred from the opposite end of the thermoelectric conversion film to a path to the second heat transfer part through the protrusion of the second heat transfer part joined to the second surface of the substrate.

A substrate portion corresponding to an arrangement position of the protrusion of the first heat transfer part reaches a high temperature over the entirety of the substrate in the thickness direction due to heat transferred from the first heat transfer part. In addition, a substrate portion corresponding to an arrangement position of the protrusion of the second heat transfer part reaches a low temperature over the entirety of the substrate in the thickness direction due to a heat dissipation effect or a cooling effect by the second heat transfer part.

As a result, over the entirety of the substrate in the thickness direction, a great temperature difference occurs in a direction along a substrate surface, and thus there is a problem that a fracture or a crack of the substrate occurs in association with thermal shock due to the rapid temperature variation or repeated temperature variation.

An object of the disclosure is to provide a thermoelectric conversion device in which a fracture or a crack of a substrate is less likely to occur.

### Solution to Problem

(1) According to an aspect of the disclosure, there is provided a thermoelectric conversion device including: a substrate including a first surface and a second surface which are opposite to each other in a thickness direction; a thermoelectric conversion film that is disposed on the first surface; a heat transfer portion that is disposed on a first surface side and performs heat transfer with the thermoelectric conversion film; and a first heat transfer part that is disposed on a second surface side. A low heat conduction portion having heat conductivity lower than heat conductivity of the heat transfer portion is provided in a portion that is adjacent to the heat transfer portion in an in-plane direction of the substrate. The substrate is joined to the first heat transfer part in a region of the second surface which is opposite to the heat transfer portion in the thickness direction.

According to this, heat transfer with the thermoelectric conversion film through the heat transfer portion can be performed preferentially to heat transfer through the low heat conduction portion. Accordingly, it is possible to preferentially transfer heat to the thermoelectric conversion film through the heat transfer portion. At this time, in a portion of the substrate which corresponds to an arrangement position of the heat transfer portion, the second surface side has heat-dissipated or is cooled by the first heat transfer part, and thus a site in which a great temperature difference occurs in a direction along a substrate surface (in-plane direction of the substrate) is limited to the first surface side of the substrate in which the thermoelectric conversion film is disposed. As a result, it is possible to suppress occurrence of a fracture or a crack of the substrate in association with heat shock due to a rapid temperature variation or repetition of the temperature variation.

(2) In the thermoelectric conversion device, a plurality of the thermoelectric conversion films and a plurality of the heat transfer portions may be formed at intervals in a first direction along the in-plane direction, each of a plurality of the low heat conduction portions may be formed to be located between the heat transfer portions adjacent to each other in the first direction, and the substrate may be joined to the first heat transfer part over the entirety of a region of the second surface which is opposite to a region ranging from one heat transfer portion out of two of the heat transfer portions adjacent to each other in the first direction to the other heat transfer portion in the thickness direction of the substrate.

According to this, in a region of the second surface which is opposite to a region ranging from one heat transfer portion out of two of the heat transfer portions adjacent to each other in the first direction to the other heat transfer portion in the thickness direction of the substrate, for example, it is possible to prevent a hollow portion from being substantially present between the substrate and the first heat transfer part.

As a result, for example, in a case where a load is applied during manufacturing of the thermoelectric conversion device, or even in a case where a load is applied to a completed thermoelectric conversion device, it is possible to suppress occurrence of a fracture or a crack of the substrate.

(3) In the thermoelectric conversion device, the substrate may be joined to the first heat transfer part in a movable state with respect to the first heat transfer part.

According to this, distortion, which occurs between the substrate and the first heat transfer part due to a difference of a material between the substrate and the first heat transfer part, and the like, is mitigated, and thus it is possible to further suppress occurrence of a fracture or a crack of the substrate.

(4) In the thermoelectric conversion device, a paste-like substance may be provided between the substrate and the first heat transfer part.

According to this, a frictional resistance between the substrate and the first heat transfer part is reduced, and thus it is possible to maintain a smooth operation state of the first heat transfer part with respect to the substrate. As a result, it is possible to further suppress a fracture or a crack of the substrate.

(5) The thermoelectric conversion device may further include a second heat transfer part that is disposed on the first surface side and has heat conductivity higher than heat conductivity of the low heat conduction portion, and the second heat transfer part may perform heat transfer with the thermoelectric conversion films through the heat transfer portion.

According to this, for example, the second heat transfer part can be allowed to function as a heat receiving member, and it is possible to preferentially transfer heat received by the second heat transfer part to the thermoelectric conversion film through the heat transfer portion with efficiency.

(6) In the thermoelectric conversion device, the low heat conduction portion may be a cavity portion.

According to this, since the low heat conduction portion is a cavity portion, that is, a so-called gap filled with air, it is possible to conveniently construct the low heat conduction portion. In addition, it is possible to set heat conductivity of the low heat conduction portion to be significantly lower than that of the heat transfer portion, and thus it is possible to transfer heat to the thermoelectric conversion film through the heat transfer portion in a more selective manner.

In addition, the thermoelectric conversion device according to the disclosure may employ the following aspects.

(7) According to another aspect of the disclosure, there is provided a thermoelectric conversion device including: a substrate including a first surface and a second surface which are opposite to each other in a thickness direction; a thermoelectric conversion film that is disposed on the first surface; a first heat transfer part having heat conductivity higher than heat conductivity of air; and a second heat transfer part having heat conductivity higher than heat conductivity of air. The first heat conductivity part includes a plate-shaped member and a protrusion that is provided on one surface of the plate-shaped member. The first heat transfer part is disposed on the first surface side. An end of the thermoelectric conversion film is joined to the protrusion directly or through a member having heat conductivity higher than heat conductivity of air. The second heat transfer part is disposed on the second surface side. The substrate is joined to the second heat transfer part in a region of the second surface which is opposite to the protrusion in the thickness direction.

(8) In the thermoelectric conversion device according to the aspect of the disclosure, a plurality of the thermoelectric conversion films may be provided on the first surface, the first heat transfer part may include a plurality of the protrusions which are provided on the one surface of the plate-shaped member, the end of each of the plurality of thermoelectric conversion films may be joined to at least one of the plurality of protrusions directly or through a member having heat conductivity higher than heat conductivity of air, and the substrate may be joined to the second heat transfer part at the entirety of a region of the second surface which is opposite to a region ranging from one protrusion out of two of the protrusions adjacent to each other to the other protrusion in the thickness direction of the substrate.

### Effects of Disclosure

According to the disclosure, it is possible to provide a thermoelectric conversion device in which a fracture or a crack of a substrate is less likely to occur.

### BRIEF DESCRIPTION OF DRAWINGS

FIG. 1 is a cross-sectional view illustrating a thermoelectric conversion device according to a first embodiment.

FIG. 2 is a top view illustrating the thermoelectric conversion device according to the first embodiment.

FIG. 3 is a graph illustrating a temperature distribution of the thermoelectric conversion device according to the first embodiment.

FIG. 4 is a cross-sectional view illustrating a thermoelectric conversion device that is a comparison object.

FIG. 5 is a graph illustrating a temperature distribution of the thermoelectric conversion device that is the comparison object.

FIG. 6 is a cross-sectional view illustrating a thermoelectric conversion device according to a second embodiment.

FIG. 7 is a cross-sectional view illustrating a thermoelectric conversion device according to a third embodiment.

FIG. 8 is a cross-sectional view illustrating a thermoelectric conversion device according to a fourth embodiment.

FIG. 9 is a cross-sectional view illustrating a thermoelectric conversion device according to a modification example of the first embodiment.

FIG. 10 is a cross-sectional view illustrating a thermoelectric conversion device according to another modification example of the first embodiment.

### DESCRIPTION OF EMBODIMENTS

Hereinafter, embodiments of the disclosure will be described in detail with reference to the accompanying drawings. Furthermore, the disclosure is not limited by contents described in the following embodiments. In addition, constituent elements which can be easily assumed by those skilled in the art, substantially the same constituent elements, and constituent elements in an equivalent range are included in the following constituent elements. In addition, the following constituent elements can be appropriately combined. In addition, various omissions, substitutions, and changes of the constituent elements can be made within a scope not departing from the gist of the disclosure.

### First Embodiment

Hereinafter, a thermoelectric conversion device 1 according to a first embodiment will be described with reference to the accompanying drawings.

### (Basic Structure)

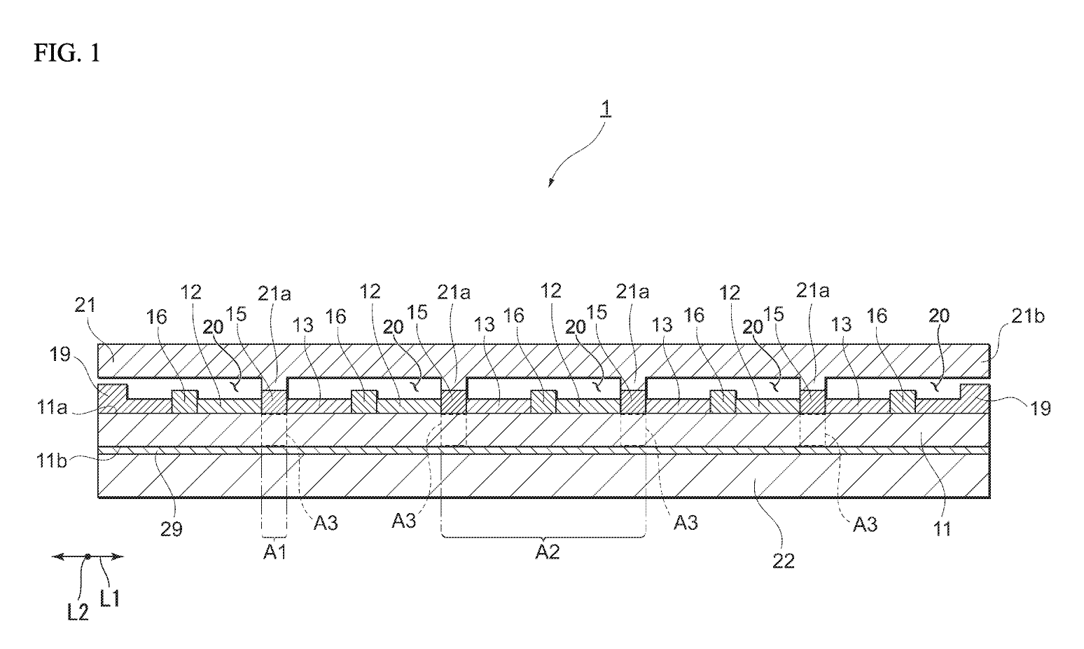

FIG. 1 is a cross-sectional view illustrating an example of the thermoelectric conversion device 1 according to the first embodiment.

As illustrated in FIG. 1, the thermoelectric conversion device 1 according to this embodiment includes a substrate 11 including a first surface 11a and a second surface 11b which are opposite to each other in a thickness direction, a thermoelectric conversion film (a plurality of first thermoelectric conversion films 12 and a plurality of second thermoelectric conversion films 13) disposed on the first surface 11a, a first heat transfer part 22 having heat conductivity higher than heat conductivity of air, and a second heat transfer part 21 having heat conductivity higher than heat conductivity of air.

In this embodiment, the second heat transfer part 21 side along a thickness direction of the substrate 11 is referred to as an upper side, and a side along a thickness direction opposite to the upper side is referred to as a downward side. That is, a direction toward the first surface 11a from the second surface 11b of the substrate 11 is referred to as the upper side, and a direction opposite to the upper side is referred to as the downward side. In addition, one direction among in-plane directions of the substrate 11 is referred to as a first direction L1, and a direction orthogonal to the first direction L1 is referred to as a second direction L2.

The second heat transfer part 21 includes a plate-shaped member 21b, and a protrusion 21a that is provided on one surface of the plate-shaped member 21b. In the example illustrated in FIG. 1, the second heat transfer part 21 includes a plurality of the protrusions 21a provided on one surface (lower surface) of the plate-shaped member 21b. The plurality of protrusions 21a protrude from the lower surface of the plate-shaped member 21b toward the downward side and are arranged in the first direction L1 at regular intervals.

FIG. 1 is a cross-sectional view of the thermoelectric conversion device 1 in a plane that is parallel to a direction (that is, the first direction L1) in which the plurality of protrusions 21a are arranged and the thickness direction of the substrate 11.

The second heat transfer part 21 is disposed on the first surface 11a side of the substrate 11, that is, on the upper side of the substrate 11. Each end of a plurality of the thermoelectric conversion films (the plurality of first thermoelectric conversion films 12 and the plurality of second thermoelectric conversion films 13) is joined to at least one of the plurality of protrusions 21a (a protrusion 21a corresponding to the each end of the thermoelectric conversion films among the plurality of protrusions 21a) through a first electrode 15. Here, the first electrode 15 is a member having heat conductivity higher than heat conductivity of air.

More specifically, the thermoelectric conversion device 1 includes the plurality of first thermoelectric conversion films 12 and the plurality second thermoelectric conversion films 13. The first thermoelectric conversion films 12 and the second thermoelectric conversion films 13 are formed in the same number, and are alternately arranged on the first surface 11a at regular intervals in the first direction L1.

An end on one side of each of the first thermoelectric conversion films 12 (that is, an end on one side in the first direction L1 in which the plurality of protrusions 21a are arranged, and a right end in FIG. 1) is joined to a corresponding protrusion 21a (that is, a protrusion 21a that is closest to the end on one side of each of the first thermoelectric conversion films 12) through the first electrode 15.

An end on one side of each of the second thermoelectric conversion films 13 (that is, an end on one side in the first direction L1 in which the plurality of protrusions 21a are arranged, and a left end in FIG. 1) is joined to a corresponding protrusion 21a (that is, a protrusion 21a closest to the end on one side of each of the second thermoelectric conversion films 13) through the first electrode 15.

The protrusion 21a and the first electrode 15 are thermally joined to each other, for example, through an insulating member (not illustrated). As an insulating member that is used in the joining between the protrusion 21a and the first electrode 15, for example, a member having heat conductivity higher than heat conductivity of air is used. Examples of a material of the insulating member in this case include a UV curable resin and a silicon-based resin.

In addition, the end on one side of each of the first thermoelectric conversion films 12 (the right end in FIG. 1) and the end on one side of each of the second thermoelectric conversion films 13 (the left end in FIG. 1) are connected to each other through the first electrode 15. An end on the other side of each of the first thermoelectric conversion films 12 (a left end in FIG. 1) and an end on the other side of each of the second thermoelectric conversion films 13 (a right end in FIG. 1) are connected to each other through a second electrode 16.

As described above, the first thermoelectric conversion film 12 and the second thermoelectric conversion film 13 are electrically connected in series through the first electrode 15 and the second electrode 16.

A terminal 19 is connected to both ends of the plurality of first thermoelectric conversion films 12 and the plurality of second thermoelectric conversion films 13 which are alternately arranged on the first surface 11a in the first direction L1 through the second electrode 16.

The first heat transfer part 22 is disposed on the second surface 11b side of the substrate 11, that is, on a downward side of the substrate 11. The substrate 11 is joined to the first heat transfer part 22 in a region A1 of the second surface 11b which is opposite to the protrusion 21a in the thickness direction of the substrate 11.

In the example illustrated in FIG. 1, the substrate 11 is joined to the first heat transfer part 22 over the entirety of a region A2 of the second surface 11b which is opposite to a region ranging from one protrusion 21a out of two protrusions 21a adjacent to each other in the first direction L1 to the other protrusion 21a in the thickness direction of the substrate 11.

More specifically, the thermoelectric conversion device 1 includes a paste-like substance 29 between the substrate 11 and the first heat transfer part 22. The substrate 11 is joined to the first heat transfer part 22 through the paste-like substance 29 over the entirety of the region A2.

According to this, the substrate 11 is joined to the first heat transfer part 22 through the second surface 11b in a movable state with respect to the first heat transfer part 22. That is, the substrate 11 is joined to the first heat transfer part 22 through the second surface 11b in a movable state (in a relatively movable state) in an in-plane direction of the substrate 11 with respect to the first heat transfer part 22.

In the example illustrated in FIG. 1, the substrate 11 and the first heat transfer part 22 are joined to each other by even planes over the entirety of the region A2. In addition, in the example illustrated in FIG. 1, in all of a plurality of the regions A2, the substrate 11 is joined to the first heat transfer part 22 over the entirety of the regions A2

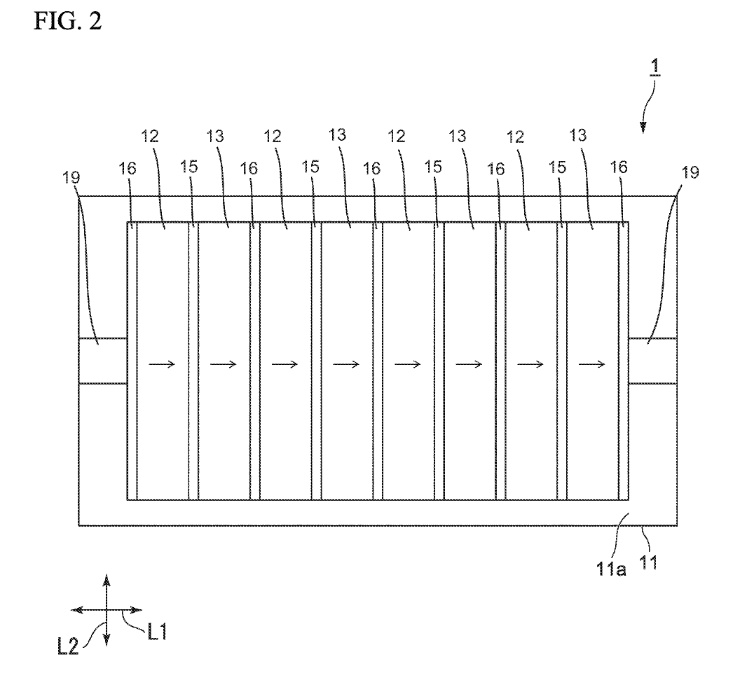

FIG. 2 is a top view when the thermoelectric conversion device 1 is seen from the first surface 11a side in the thickness direction of the substrate 11. In FIG. 2, the second heat transfer part 21 is not illustrated.

As illustrated in FIG. 2, the first thermoelectric conversion film 12 and the second thermoelectric conversion film 13 are alternately arranged on the first surface 11a in the first direction L1, and are electrically connected in series through the first electrode 15 and the second electrode 16.

### (Substrate)

The substrate 11 is formed in a rectangular shape elongated in the first direction L1 in comparison to the second direction L2 in a plan view. However, the shape of the substrate 11 is not limited thereto, and may be formed in a cubic shape in a plan view as an example.

Examples of the substrate 11 include a high-resistance silicon (Si) substrate having a sheet resistance of 10Ω or greater. The first thermoelectric conversion film 12 and the second thermoelectric conversion film 13 are formed on the first surface 11a. Furthermore, when considering prevention of electric short-circuit between the plurality of thermoelectric conversion films 12 and 13, a high-resistance substrate having sheet resistance of 10Ω or greater is preferable as the substrate 11.

As an example of the substrate 11, in addition to the high-resistance silicon (Si) substrate, for example, a high-resistance SOI substrate including an oxidation insulating layer in a substrate, another high-resistance signal crystal substrate, or a ceramic substrate can also be used. In addition, even in a low-resistance substrate having sheet resistance of 10Ω or less, a substrate in which a high-resistance material is disposed on a surface of the low-resistance substrate, which is obtained by disposing the high-resistance material between the low-resistance substrate and the first thermoelectric conversion film 12 and the second thermoelectric conversion film 13, can be used as the substrate 11.

### (Thermoelectric Conversion Film)

The first thermoelectric conversion film 12 and the second thermoelectric conversion film 13 are respectively formed in a rectangular shape elongated in the second direction L2 in comparison to the first direction L1 in a plan view, and are formed in the same shape and the same size. The first thermoelectric conversion film 12 and the second thermoelectric conversion film 13 are formed of a thermoelectric conversion film of an n-type semiconductor and a thermoelectric conversion film of a p-type semiconductor.

Specifically, the first thermoelectric conversion film 12 is a multi-layer film of an n-type silicon (Si) and an n-type silicon-germanium alloy (SiGe) which are doped with antimony (Sb) having a high-concentration (10¹⁸ to 10¹⁹ cm⁻³), and functions as an n-type semiconductor. The second thermoelectric conversion film 13 is a multi-layer film of a p-type silicon (Si) and a p-type silicon-germanium alloy (SiGe) which are doped with boron (B) having a high-concentration (10¹⁸ to 10¹⁹ cm⁻³), and functions as a p-type semiconductor.

The plurality of first thermoelectric conversion films 12 may be set as n-type semiconductor multi-layer films having the same configuration or n-type semiconductor multi-layer films having configurations different from each other. In addition, the plurality of second thermoelectric conversion films 13 may be set as p-type semiconductor multi-layer films having the same configuration or p-type semiconductor multi-layer films having configurations different from each other.

In a case where the thermoelectric conversion films are set as the n-type semiconductors, a current flows from a cold junction side toward a hot junction side, and in a case where the thermoelectric conversion films are the p-type semiconductors, a current flows from the hot junction side toward the cold junction side.

In addition, each of the first thermoelectric conversion films 12 and each of the second thermoelectric conversion films 13 are not limited to the semiconductor multi-layer films, and may be single-layer films of a p-type or n-type semiconductor. Furthermore, as the semiconductors, an oxide semiconductor can also be used. In addition, for example, the first thermoelectric conversion film 12 and the second thermoelectric conversion film 13 may be a thermoelectric conversion film formed of an organic polymer film, a metal film, or the like.

The first thermoelectric conversion film 12 and the second thermoelectric conversion film 13 are formed on the first surface 11a of the substrate 11, for example, by using a sputtering device under an ultra-high vacuum (<10⁻⁵ Pa) condition, and are formed to form a plurality of pairs through etching.

### (Second Heat Transfer Part)

The second heat transfer part 21 can function as a heat receiving member in the thermoelectric conversion device 1. That is, the second heat transfer part 21 can selectively transfer heat that is received by a surface (that is, an upper surface that functions a heat receiving surface) opposite to a surface on which the protrusion 21a of the plate-shaped member 21b is formed to the first electrode 15 formed on the first surface 11a of the substrate 11 through the protrusion 21a.

It is preferable that heat conductivity of the second heat transfer part 21 is higher than heat conductivity of the substrate 11. As a material of the second heat transfer part 21, a metal is preferable, and particularly, a material that has high heat conductivity and is easily to be processed into a convex shape is preferable. Examples of the material include aluminum (Al), or a copper (Cu).

The second heat transfer part 21 is formed in a rectangular shape elongated in the first direction L1 in comparison to the second direction L2 in a plan view in correspondence with the shape of the substrate 11, and is formed in the same size as that of an external shape of the substrate 11. However, an external size of the second heat transfer part 21 is not limited, and the second heat transfer part 21 may be formed, for example, in a flat plate shape having an external size greater than that of the substrate 11.

A plurality of the protrusions 21a are formed in correspondence with the number of a plurality of the first electrodes 15, and are disposed with an interval in the first direction L1 to face the first electrodes 15 from an upper side thereof.

Since the plurality of protrusions 21a are formed on the plate-shaped member 21b in the second heat transfer part 21, a cavity portion (low heat conduction portion in the disclosure) 20 is provided at a portion adjacent to the protrusions 21a in an in-plane direction of the substrate 11, that is, a portion located between the protrusions 21a adjacent to each other in the first direction L1. In the example illustrated in FIG. 1, the low heat conduction portion (cavity portion 20) is set between the protrusions 21a adjacent to each other in the first direction L1.

The cavity portion 20 is a space (that is, an air layer) formed between a lower surface of the plate-shaped member 21b excluding a site at which the protrusion 21a is formed, and the thermoelectric conversion film (first thermoelectric conversion film 12 and the second thermoelectric conversion film 13) and the second electrode 16, and the cavity portion 20 has heat conductivity lower than heat conductivity of the protrusion 21a.

As described above, the second heat transfer part 21 including the protrusion 21a and the first electrode 15 have heat conductivity higher than heat conductivity of air. Accordingly, heat received by the second heat transfer part 21 is preferentially transferred to the first electrode 15 through the protrusion 21a, and can be transferred to the first thermoelectric conversion film 12 and the second thermoelectric conversion film 13 through the first electrode 15.

That is, heat received by the second heat transfer part 21 is preferentially transferred to the first thermoelectric conversion film 12 side and the second thermoelectric conversion film 13 side through the protrusion 21a and the first electrode 15 in preference to transfer to the first thermoelectric conversion film 12 side and the second thermoelectric conversion film 13 side through the cavity portion 20 without through the protrusion 21a.

In addition, the above-described plurality of protrusions 21a are disposed on the first surface 11a side of the substrate 11, and function as a heat transfer portion that performs heat transfer between the first thermoelectric conversion film 12 and the second thermoelectric conversion film 13. That is, in this embodiment, the protrusions 21a function as a part of the second heat transfer part 21, and also function as a heat transfer portion.

### (First Heat Transfer Part)

The first heat transfer part 22 is disposed on the second surface 11b side on which the thermoelectric conversion film of the substrate 11 is not formed. It is possible to dissipate the heat that is received by the substrate 11 or cool the substrate 11 in the thermoelectric conversion device 1 due to the first heat transfer part 22.

It is preferable that the heat conductivity of the first heat transfer part 22 is higher than the heat conductivity of the substrate 11. As a material of the first heat transfer part 22, a metal is preferable, and particularly, a material having high heat conductivity is preferable. Examples of the material include aluminum (Al) or copper (Cu).

It is preferable that the first heat transfer part 22 has a shape suitable for heat dissipation or cooling. For example, it is preferable that the first heat transfer part 22 includes a flow passage for cooling with air or cooling with water on an inner side. In addition, it is preferable that the first heat transfer part 22 has a fin configuration for heat exchange on a surface opposite to a surface for joining with the substrate 11.

### (Paste-Like Substance)

The paste-like substance 29 is disposed between the substrate 11 and the first heat transfer part 22. A frictional resistance between the substrate 11 and the first heat transfer part 22 is reduced due to the paste-like substance 29.

Examples of a specific material of the paste-like substance 29 include silicon grease including a high heat conduction material such as silver (Ag) and diamond (C) as filler. Particularly, it is preferable that heat conductivity of the paste-like substance 29 is higher than heat conductivity of air from the viewpoint of raising heat conductivity between the substrate 11 and the first heat transfer part 22.

(Electrode) The first electrode 15 and the second electrode 16 are disposed between the first thermoelectric conversion film 12 and the second thermoelectric conversion film 13, which are formed on the first surface 11a of the substrate 11, and electrically connect the films.

In addition, the protrusion 21a of the second heat transfer part 21 is thermally connected to the first electrode 15. According to this, in the thermoelectric conversion device 1, the first electrode 15 becomes a hot junction that transfers heat from the second heat transfer part 21 to the first thermoelectric conversion film 12 and the second thermoelectric conversion film 13.

As a material of the first electrode 15 and the second electrode 16, a metal is preferable, and particularly, a material which has high electric conductivity and heat conductivity and of which shape processing through patterning is easily performed is preferable. Examples of the material include copper (Cu) and gold (Au).

The protrusion 21a of the second heat transfer part 21 is not joined to the second electrode 16. The second electrode 16 is disposed on the first surface 11a of the substrate 11 at a position corresponding to the center between protrusions 21a adjacent to each other in the first direction L1. According to this, in the thermoelectric conversion device 1, an arrangement position of the second electrode 16 is set to a position on the first surface 11a which is farthest from the protrusion 21a and the first electrode 15 in the first direction L1. Accordingly, the second electrode 16 becomes a cold junction.

### (Terminal)

The terminal 19 becomes an electrical starting end and an electrical terminal end of a thermoelectric conversion circuit including the first thermoelectric conversion film 12, the second thermoelectric conversion film 13, the first electrode 15, the second electrode 16, and the terminal 19, and is connected to an outside for taking out an electromotive force from the thermoelectric conversion device 1.

As a material of the terminal 19, a metal is preferable, and particularly, a material which has high electric conductivity and heat conductivity and of which shape processing through patterning is easy is preferable. Examples of the material include copper (Cu) and gold (Au).

### (Description of Effect)

In the thermoelectric conversion device 1, thermoelectric conversion is performed by using a Seebeck effect of the first thermoelectric conversion film 12 and the second thermoelectric conversion film 13. Expression (1) is a relational formula relating to the Seebeck effect.

E=S×|ΔT| (1)

In accordance with Expression (1), an electric field (electromotive force) E(V) obtained through the thermoelectric conversion is defined by a Seebeck coefficient S(V/K) that is a material constant of the first thermoelectric conversion film 12 and the second thermoelectric conversion film 13, and a temperature difference ΔT(K) between one end and the other end of the first thermoelectric conversion film 12 or the second thermoelectric conversion film 13.

Heat that is received by the second heat transfer part 21 at an upper surface of the plate-shaped member 21b (that is, a surface opposite to a surface on which the protrusion 21a is formed) is selectively transferred to the first electrode 15 through the protrusion 21a, and the first electrode 15 becomes a hot junction.

In addition, the second electrode 16, which is disposed at a position on the first surface 11a which is farthest from the protrusion 21a and the first electrode 15 in the first direction L1, becomes a cold junction. In the first thermoelectric conversion film 12 and the second thermoelectric conversion film 13, which are respectively interposed between first electrode 15 that is the hot junction and the second electrode 16 that is the cold junction, a temperature difference occurs between both ends of each of the first and second electrodes 15 and 16. According to this, it is possible to obtain an electromotive force from the first thermoelectric conversion film 12 and the second thermoelectric conversion film 13 in association with the Seebeck effect.

In a case where a thermoelectric conversion film is an n-type semiconductor, a current flows from the cold junction side toward the hot junction side, and in a case where the thermoelectric conversion film is a p-type semiconductor, a current flows from the hot junction side toward the cold junction side. According to this, in the thermoelectric conversion device 1, an electromotive force of the same direction is generated in the first thermoelectric conversion film 12 and the second thermoelectric conversion film 13.

Accordingly, the electromotive force that is generated in each of a plurality of the first thermoelectric conversion films 12 and a plurality of the second thermoelectric conversion films 13 is taken out as the sum of the electromotive forces from the terminal 19 that becomes the electrical terminal end of the thermoelectric conversion circuit. In FIG. 2, a direction of a current that flows to the first thermoelectric conversion films 12 and the second thermoelectric conversion films 13 is indicated by an arrow.

To increase the electromotive force by enlarging a temperature difference between both ends of each of the first thermoelectric conversion film 12 and the second thermoelectric conversion film 13, it is preferable to make a distance between an end on the other side of each of the thermoelectric conversion films (that is, an end on a side distant from the protrusion 21a (a cold junction-side end)) and the first heat transfer part 22 (in the example illustrated in FIG. 1, the sum of the thickness of the substrate 11 and the thickness of the paste-like substance 29) be smaller than a distance between both ends (between both the hot junction-side end and the cold junction-side end) of each of the thermoelectric conversion films (each of the first thermoelectric conversion film 12 and the second thermoelectric conversion film 13) (that is, a distance between the second electrode 16 and the first electrode 15 which are adjacent to each other in the first direction L1).

According to this configuration, an end on the other side of each of the thermoelectric conversion films is more susceptible to a cooling or heat dissipation operation from the first heat transfer part 22 in comparison to a heat transfer operation from the first electrode 15. Accordingly, a temperature of the end on the other side of each of the thermoelectric conversion films is maintained to be low, and thus it is possible to enlarge a temperature difference between both ends of each of the first thermoelectric conversion film 12 and the second thermoelectric conversion film 13.

Heat that is transferred from the second heat transfer part 21 to the first electrode 15 through the protrusion 21a is also transferred to the substrate 11. However, the substrate 11 is joined to the first heat transfer part 22 in the region A1 that is opposite to the protrusion 21a in the thickness direction of the substrate 11. According to this, in a portion A3 of the substrate 11, which corresponds to an arrangement position of the protrusion 21a, the second surface 11b side is heat-dissipated or cooled by the first heat transfer part 22.

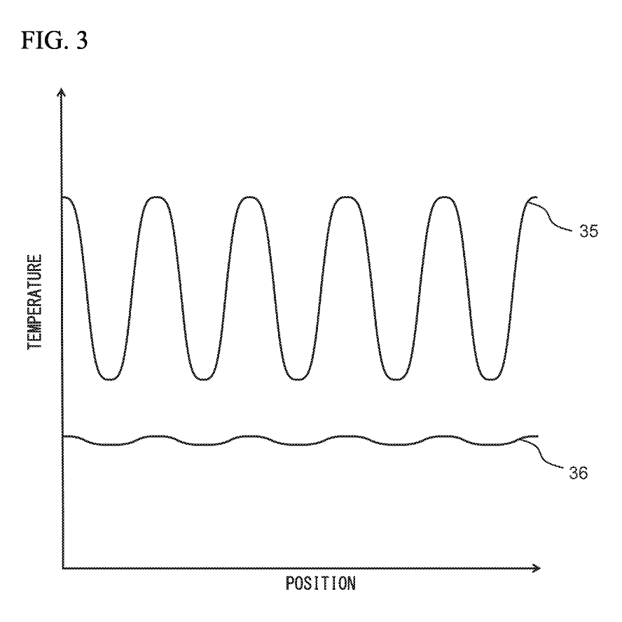

According to this, as illustrated in FIG. 3, in temperature variations along a substrate surface of the substrate 11, a temperature variation on the second surface 11b which is indicated by a plotting line 36 becomes smaller than a temperature variation on the first surface 11a which is indicated by a plotting line 35.

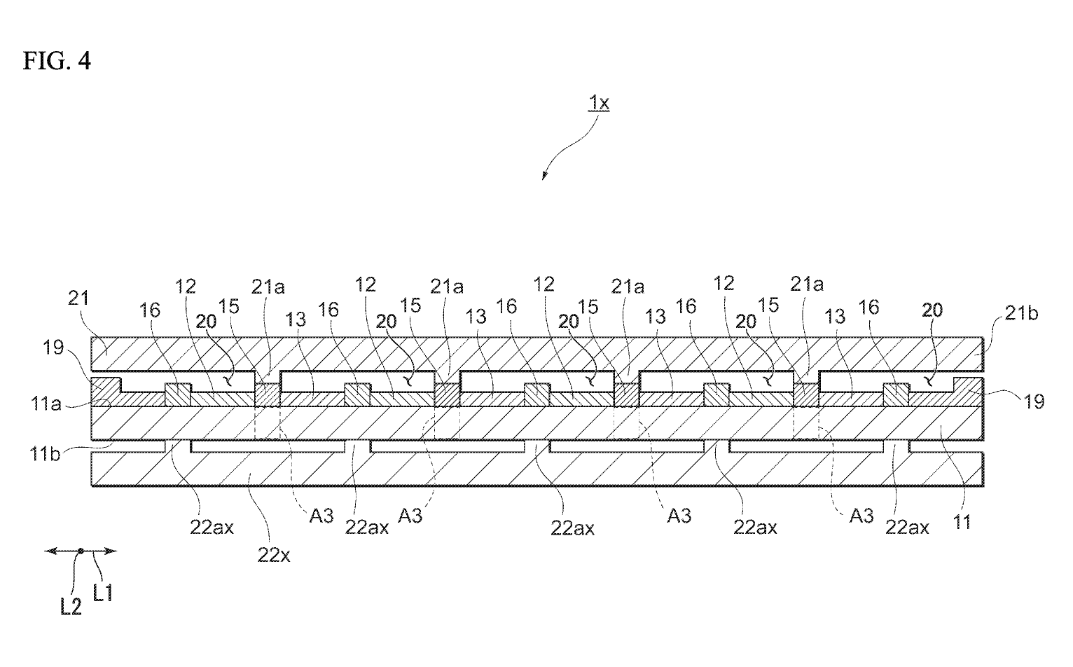

As a comparison object, a thermoelectric conversion device 1x is illustrated in FIG. 4.

The thermoelectric conversion device 1x includes a first heat transfer part 22x instead of the first heat transfer part 22 and the paste-like substance 29 of the thermoelectric conversion device 1. The other configurations of the thermoelectric conversion device 1x are the same as those of the thermoelectric conversion device 1.

The first heat transfer part 22x includes a protrusion 22ax, and the protrusion 22ax is joined to a position of the second surface 11b which corresponds to a formation position of the second electrode 16 in the first surface 11a in the thickness direction of the substrate 11.

According to this, heat transferred from the second heat transfer part 21 to the first electrode 15 through the protrusion 21a is also transferred to the substrate 11. However, the portion A3 of the substrate 11, which corresponds to the arrangement position of the protrusion 21a of the second heat transfer part 21, is less susceptible to the heat dissipation effect or the cooling effect due to the first heat transfer part 22x, and thus the substrate 11 reaches a high temperature in a region having a center at the portion A3. On the other hand, the substrate 11 reaches a low temperature in a region having a center at a joining portion with the protrusion 22ax due to the heat dissipation effect or the cooling effect by the first heat transfer part 22x.

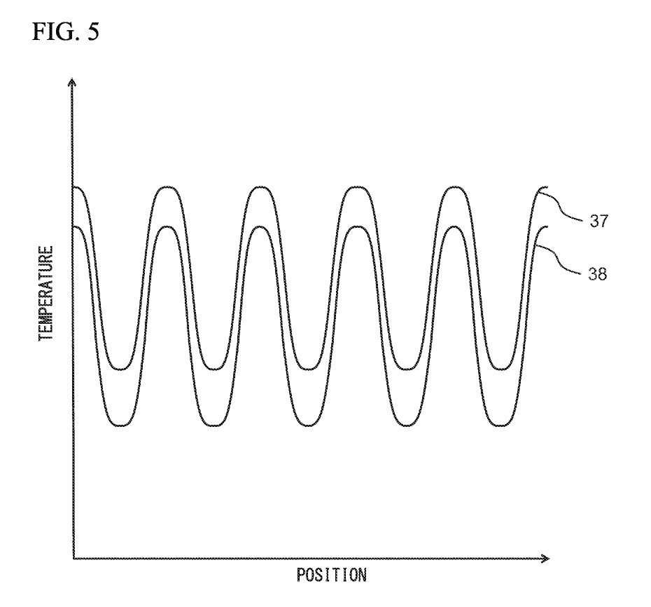

According to this, in the thermoelectric conversion device 1x, as illustrated in FIG. 5, in temperature variations along a substrate surface of the substrate 11, a temperature variation in the second surface 11b which is indicated by a plotting line 38 is enlarged as in a temperature variation in the first surface 11a which is indicated by a plotting line 37.

As described above, in the thermoelectric conversion device 1x as a comparison object, over the entirety of the substrate 11 in the thickness direction, a great temperature difference occurs in a direction along a substrate surface, and thus a fracture or a crack of the substrate is likely to occur in association with thermal shock due to a rapid temperature variation or a repeated temperature variation.

In addition, in the thermoelectric conversion device 1x as a comparison object, a hollow portion exists between the substrate 11 and the first heat transfer part 22x. Accordingly, for example, in a case where a load is applied during manufacturing of the thermoelectric conversion device 1x, or even in a case where a load is applied to a completed thermoelectric conversion device 1x, a fracture or a crack of the substrate 11 is likely to occur.

In contrast, according to the thermoelectric conversion device 1 in this embodiment, the substrate 11 is joined to the first heat transfer part 22 in the region A1. According to this, in the portion A3 of the substrate 11 which corresponds to the arrangement position of the protrusion 21a of the second heat transfer part 21, the second surface 11b side is heat-dissipated or cooled due to the first heat transfer part 22. Accordingly, a site at which a great temperature difference occurs in a direction along a substrate surface of the substrate 11 is limited to the first surface 11a side of the substrate 11 in which the thermoelectric conversion film is disposed as illustrated in FIG. 3. As a result, it is possible to suppress occurrence of a fracture or a crack of the substrate 11 in association with heat shock due to a rapid temperature variation or a repeated temperature variation.

In addition, in the thermoelectric conversion device 1, the substrate 11 is joined to the first heat transfer part 22 over the entirety of the region A2, and thus a hollow portion substantially does not exist between the substrate 11 and the first heat transfer part 22 in the region A2. Accordingly, for example, in a case where a load is applied during manufacturing of the thermoelectric conversion device 1, or even in a case where a load is applied to a completed thermoelectric conversion device 1, it is possible to suppress occurrence of a fracture or a crack of the substrate 11.

In addition, in the thermoelectric conversion device 1, the substrate 11 is joined to the first heat transfer part 22 in a movable state with respect to the first heat transfer part 22 in an in-plane direction of the substrate 11. Accordingly, distortion, which occurs between the substrate 11 and the first heat transfer part 22 due to a difference of a material between the substrate 11 and the first heat transfer part 22, and the like, is mitigated, and thus it is possible to further suppress occurrence of a fracture or a crack of the substrate 11.

In addition, the thermoelectric conversion device 1 includes the paste-like substance 29 between the substrate 11 and the first heat transfer part 22, and thus a frictional resistance between the substrate 11 and the first heat transfer part 22 is reduced. Accordingly, it is possible to maintain a smooth operation state of the first heat transfer part 22 with respect to the substrate 11. As a result, it is possible to further suppress a fracture or a crack of the substrate 11.

Furthermore, in the thermoelectric conversion device 1 of the first embodiment, description has been given of an example in which an end of each of a plurality of thermoelectric conversion films (a plurality of the first thermoelectric conversion films 12 and a plurality of the second thermoelectric conversion films 13) is joined to the protrusion 21a through an insulating member and the first electrode 15, which have heat conductivity higher than heat conductivity of air, but there is no limitation thereto.

For example, respective ends of the plurality of thermoelectric conversion films (the plurality of first thermoelectric conversion films 12 and the plurality of second thermoelectric conversion films 13) may be joined to a plurality of the protrusions 21a through an insulating member having heat conductivity higher than heat conductivity of air without using the first electrode 15.

In addition, in this case, for example, in a case where a surface of the protrusion 21a is set to an insulating layer, and thus electric conduction between the second heat transfer part 21 and the thermoelectric conversion film (the first thermoelectric conversion film 12 and the second thermoelectric conversion film 13) is not established, or in a case where electric conduction between the second heat transfer part 21 and the thermoelectric conversion film (the first thermoelectric conversion film 12 and the second thermoelectric conversion film 13) does not become a problem, respective ends of a plurality of the thermoelectric conversion films (a plurality of the first thermoelectric conversion films 12 and a plurality of the second thermoelectric conversion films 13) may be directly joined to a plurality of the protrusions 21a.

In addition, in the thermoelectric conversion device 1 of the first embodiment, the second heat transfer part 21 may be constructed by a plurality of members. In addition, the protrusion 21a of the second heat transfer part 21 may be allowed to serve as the first electrode 15. In addition, the first heat transfer part 22 may be constructed by a plurality of members.

### Second Embodiment

Hereinafter, with regard to a thermoelectric conversion device 2 according to a second embodiment, description will be mainly given of a configuration different from that of the thermoelectric conversion device 1 according to the first embodiment, and description of a common configuration will be appropriately omitted.

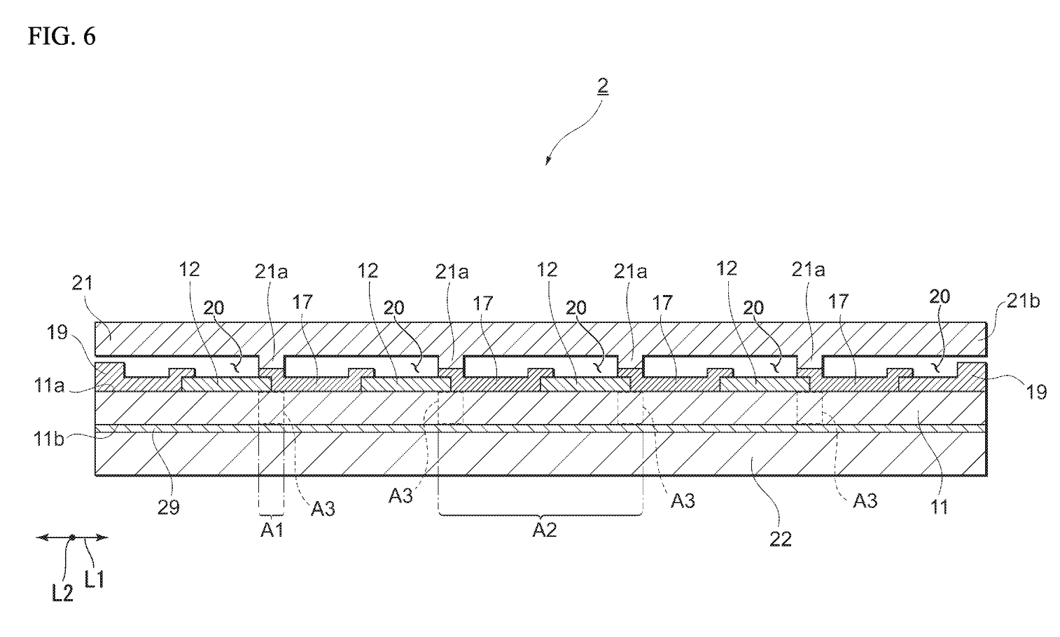

FIG. 6 illustrates a cross-sectional structure of the thermoelectric conversion device 2.

As illustrated in FIG. 6, in contrast to the thermoelectric conversion device 1 according to the first embodiment, the thermoelectric conversion device 2 according to this embodiment includes a third electrode 17 that is arranged at regular intervals in the first direction L1 instead of the second thermoelectric conversion film 13, the first electrode 15, and the second electrode 16.

Accordingly, the thermoelectric conversion film of the thermoelectric conversion device 2 is constructed by one kind of the first thermoelectric conversion film 12. Here, the third electrode 17 is a member having heat conductivity higher than heat conductivity of air. According to this, the third electrode 17 has heat conductivity higher than heat conductivity of the cavity portion 20.

FIG. 6 is a cross-sectional view of the thermoelectric conversion device 2 in a plane that is parallel to a direction (that is, the first direction L1) in which the plurality of protrusions 21a are arranged and the thickness direction of the substrate 11.

In the thermoelectric conversion device 2, an end of each of a plurality of the first thermoelectric conversion films 12 is thermally joined to at least one of the plurality of protrusions 21a (that is, a protrusion 21a corresponding to an end of each of the first thermoelectric conversion films 12 among the plurality of protrusions 21a) through the third electrode 17. In addition, the first thermoelectric conversion films 12 are electrically connected in series through the third electrode 17. A terminal 19 is connected to both ends of the plurality first thermoelectric conversion films 12 arranged on the first surface 11a in the first direction L1.

More specifically, in the thermoelectric conversion device 2, an end on one side of each of the first thermoelectric conversion films 12 (that is, an end on one side in the first direction L1 in which the plurality of protrusions 21a are arranged, and a right end in FIG. 6) is joined to a corresponding protrusion 21a (that is, a protrusion 21a that is closest to the end on one side of each of the first thermoelectric conversion films 12) through the third electrode 17.

In the first thermoelectric conversion films 12 adjacent to each other in the first direction L1, an end on one side on one of the first thermoelectric conversion films 12 (a right end in FIG. 6) and an end on the other side on the other first thermoelectric conversion film 12 (a left end in FIG. 6) are electrically connected to each other through the third electrode 17.

As in the joining between the protrusion 21a and the first electrode 15 according to the first embodiment, the protrusion 21a and the third electrode 17 are thermally joined to each other, for example, through an insulating member (not illustrated).

In the thermoelectric conversion device 2, in the third electrode 17, a portion to which the protrusion 21a is joined becomes a hot junction, and a portion that is farthest from the hot junction in the first direction L1 becomes a cold junction. According to this, in the plurality of first thermoelectric conversion films 12 which are respectively interposed between the hot junction and the cold junction, a temperature difference occurs between both ends of each of the first thermoelectric conversion films 12.

Accordingly, it is possible to obtain an electromotive force from each of the plurality of first thermoelectric conversion films 12 in association with a Seebeck effect. Furthermore, an electromotive force that is generated in each of the plurality of first thermoelectric conversion films 12 is taken out as the sum of the electromotive forces from the terminal 19 that becomes the electrical terminal end of the thermoelectric conversion circuit.

To increase the electromotive force by enlarging a temperature difference between both ends of each of the plurality of first thermoelectric conversion films 12, it is preferable to make a distance between an end on the other side of each of the first thermoelectric conversion films 12 (that is, an end on a side distant from the protrusion 21a (the cold junction-side end)) and the first heat transfer part 22 (in the example illustrated in FIG. 2, the sum of the thickness of the substrate 11 and the thickness of the paste-like substance 29) be shorter than a distance between both ends of each of the first thermoelectric conversion films 12 (between the hot junction-side end and the cold junction-side end).

According to this configuration, an end on the other side of the first thermoelectric conversion film 12 is more susceptible to a cooling or heat dissipation operation from the first heat transfer part 22 in comparison to a heat transfer operation from the hot junction. Accordingly, a temperature of the end on the other side of the first thermoelectric conversion film 12 is maintained to be low, and thus it is possible to enlarge a temperature difference between both ends of the first thermoelectric conversion film 12. The other configurations of the thermoelectric conversion device 2 are the same as those of the thermoelectric conversion device 1 according to the first embodiment.

As a material of the third electrode 17, a metal is preferable, and particularly, a material which has high electric conductivity and of which shape processing through patterning is easy is preferable. Examples of the material include copper (Cu) and gold (Au).

Even in the thermoelectric conversion device 2 configured as described above according to this embodiment, as in the thermoelectric conversion device 1 according to the first embodiment, it is possible to suppress occurrence of a fracture or a crack of the substrate.

As in the thermoelectric conversion device 1 according to the first embodiment, even in the thermoelectric conversion device 2, to increase the electromotive force by enlarging the temperature difference between both ends of each of the first thermoelectric conversion films 12, it is preferable to make a distance between an end on the other side of each of the first thermoelectric conversion films 12 (that is, an end on a side distant from the protrusion 21a (the cold junction-side end)) and the first heat transfer part 22 be shorter than a distance between both ends of each of the first thermoelectric conversion films 12 (between the hot junction-side end and the cold junction-side end).

According to this configuration, an end on the other side of the first thermoelectric conversion film 12 is more susceptible to a cooling or heat dissipation operation from the first heat transfer part 22 in comparison to a heat transfer operation from the protrusion 21a. Accordingly, a temperature of the end on the other side of each of the first thermoelectric conversion films 12 is maintained to be low, and thus it is possible to enlarge a temperature difference between both ends of the first thermoelectric conversion film 12.

In addition, in the thermoelectric conversion device 2, as the first thermoelectric conversion film 12, for example, the p-type semiconductor as described above as the second thermoelectric conversion film 13 in the first embodiment may be used.

### Third Embodiment

Hereinafter, with regard to a thermoelectric conversion device 3 according to a third embodiment, description will be mainly given of a configuration different from that of the thermoelectric conversion device 1 according to the first embodiment, and description of a common configuration will be appropriately omitted.

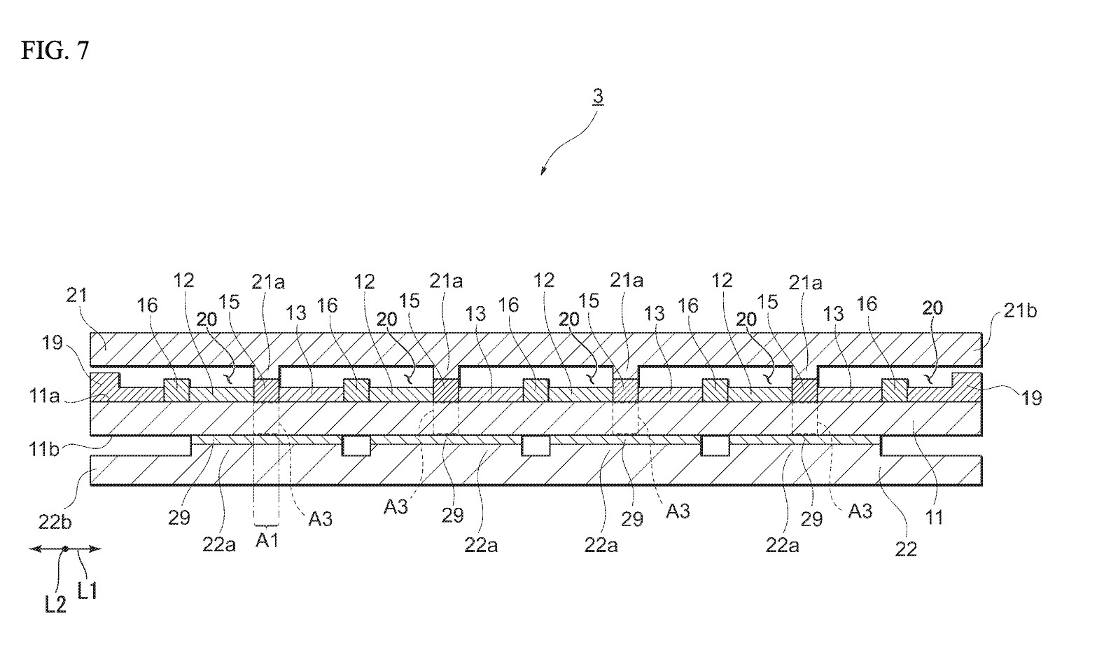

FIG. 7 illustrates a cross-sectional structure of the thermoelectric conversion device 3.

As illustrated in FIG. 7, the thermoelectric conversion device 3 according to this embodiment is different from the thermoelectric conversion device 1 according to the first embodiment in a configuration of the first heat transfer part 22.

In the thermoelectric conversion device 3, the first heat transfer part 22 includes a plate-shaped member 22b and a protrusion 22a that is provided on one surface (upper surface) of the plate-shaped member 22b. The protrusion 22a protrudes upward from the upper surface of the plate-shaped member 22b, and is disposed at regular intervals in the first direction L1.

The substrate 11 is joined to the protrusion 22a of the first heat transfer part 22 in a region A1 of the second surface 11b which is opposite to the protrusion 21a in the thickness direction of the substrate 11.

The thermoelectric conversion device 3 includes a paste-like substance 29 between the substrate 11, and the protrusion 22a of the first heat transfer part 22. Accordingly, the substrate 11 is joined to the first heat transfer part 22 through the paste-like substance 29.

The other configurations of the thermoelectric conversion device 3 are the same as those of the thermoelectric conversion device 1 according to the first embodiment. FIG. 7 is a cross-sectional view of the thermoelectric conversion device 3 in a plane that is parallel to the first direction L1 in which a plurality of the protrusions 21a are arranged and the thickness direction of the substrate 11.

Even in the thermoelectric conversion device 3 configured as described above according to this embodiment, the substrate 11 is joined to the first heat transfer part 22 in the region A1. Accordingly, in the portion A3 of the substrate 11 which corresponds to the arrangement position of the protrusions 21a of the second heat transfer part 21, the second surface 11b side can be heat-dissipated or cooled due to the first heat transfer part 22.

Accordingly, a site at which a great temperature difference occurs in a direction along a substrate surface of the substrate 11 is limited to the first surface 11a side of the substrate 11 in which the thermoelectric conversion film is disposed. As a result, it is possible to suppress occurrence of a fracture or a crack of the substrate 11 in association with heat shock due to a rapid temperature variation or the repeated temperature variation.

As in the case of the thermoelectric conversion device 1 according to the first embodiment, even in the thermoelectric conversion device 3, to increase the electromotive force by enlarging a temperature difference between both ends of each of the first thermoelectric conversion film 12 and the second thermoelectric conversion film 13, it is preferable to make a distance between an end on the other side of each of the thermoelectric conversion films (that is, an end on a side distant from the protrusion 21a (a cold junction-side end)) and the first heat transfer part 22 be smaller than a distance between both ends (between both the hot junction-side end and the cold junction-side end) of each of the thermoelectric conversion films (each of the first thermoelectric conversion film 12 and the second thermoelectric conversion film 13) (that is, a distance between the second electrode 16 and the first electrode 15 which are adjacent to each other in the first direction L1).

According to this configuration, an end on the other side of each of the thermoelectric conversion films is more susceptible to a cooling or heat dissipation operation from the first heat transfer part 22 in comparison to a heat transfer operation from the first electrode 15. Accordingly, a temperature of the end on the other side of each of the thermoelectric conversion films is maintained to be low, and thus it is possible to enlarge a temperature difference between both ends of each of the first thermoelectric conversion film 12 and the second thermoelectric conversion film 13.

### Fourth Embodiment

Hereinafter, with regard to a thermoelectric conversion device 4 according to a fourth embodiment, description will be mainly given of a configuration different from that of the thermoelectric conversion device 1 according to the first embodiment, and description of a common configuration will be appropriately omitted.

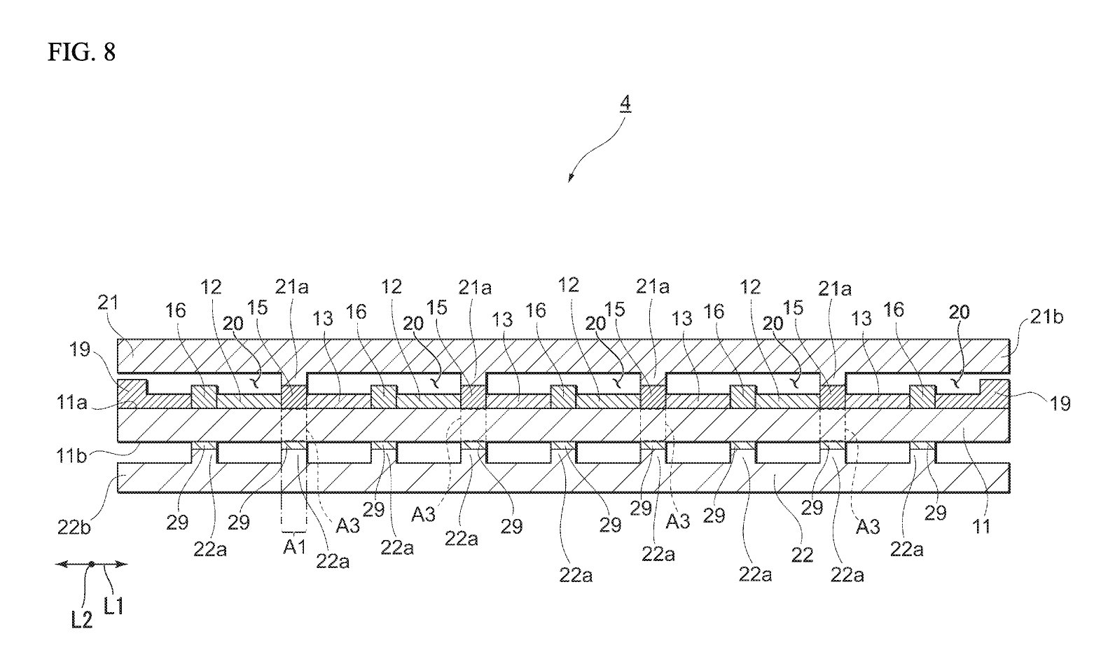

FIG. 8 illustrates a cross-sectional structure of the thermoelectric conversion device 4.

As illustrated in FIG. 8, the thermoelectric conversion device 4 according to this embodiment is different from the thermoelectric conversion device 1 according to the first embodiment in a configuration of the first heat transfer part 22. In the thermoelectric conversion device 4, the first heat transfer part 22 includes a plate-shaped member 22b and a protrusion 22a that is provided on one surface (upper surface) of the plate-shaped member 22b. The protrusion 22a protrudes upward from the upper surface of the plate-shaped member 22b, and is disposed at regular intervals in the first direction L1.

The substrate 11 is joined to the protrusion 22a of the first heat transfer part 22 in a region A1 of the second surface 11b which is opposite to the protrusion 21a in the thickness direction of the substrate 11.

The thermoelectric conversion device 4 includes a paste-like substance 29 between the substrate 11 and the protrusion 22a of the first heat transfer part 22. Accordingly, the substrate 11 is joined to the first heat transfer part 22 through the paste-like substance 29.

The other configurations of the thermoelectric conversion device 4 are the same as those of the thermoelectric conversion device 1 according to the first embodiment. FIG. 8 is a cross-sectional view of the thermoelectric conversion device 4 in a plane that is parallel to the first direction L1 in which a plurality of the protrusions 21a are arranged and the thickness direction of the substrate 11.

Even in the thermoelectric conversion device 4 configured as described above according to this embodiment, the substrate 11 is joined to the first heat transfer part 22 in the region A1. Accordingly, in the portion A3 of the substrate 11 which corresponds to the arrangement position of the protrusions 21a of the second heat transfer part 21, the second surface 11b side can be heat-dissipated or cooled due to the first heat transfer part 22.

Accordingly, a site at which a great temperature difference occurs in a direction along a substrate surface of the substrate 11 is limited to the first surface 11a side of the substrate 11 in which the thermoelectric conversion film is disposed. As a result, it is possible to suppress occurrence of a fracture or a crack of the substrate 11 in association with heat shock due to a rapid temperature variation or repetition of the temperature variation.

As in the case of the thermoelectric conversion device 1 according to the first embodiment, even in the thermoelectric conversion device 4, to increase the electromotive force by enlarging a temperature difference between both ends of each of the first thermoelectric conversion film 12 and the second thermoelectric conversion film 13, it is preferable to make a distance between an end on the other side of each of the thermoelectric conversion films (that is, an end on a side distant from the protrusion 21a (a cold junction-side end)) and the first heat transfer part 22 be smaller than a distance between both ends (between both the hot junction-side end and the cold junction-side end) of each of the thermoelectric conversion films (each of the first thermoelectric conversion film 12 and the second thermoelectric conversion film 13) (that is, a distance between the second electrode 16 and the first electrode 15 which are adjacent to each other in the first direction L1).

According to this configuration, an end on the other side of each of the thermoelectric conversion films is more susceptible to a cooling or heat dissipation operation from the first heat transfer part 22 in comparison to a heat transfer operation from the first electrode 15. Accordingly, a temperature of the end on the other side of each of the thermoelectric conversion films is maintained to be low, and thus it is possible to enlarge a temperature difference between both ends of each of the first thermoelectric conversion film 12 and the second thermoelectric conversion film 13.

In the first embodiment to fourth embodiment as described above, description has been given of an example in which the substrate 11 is joined to the first heat transfer part 22 in the region A1 through the paste-like substance 29, but there is no limitation to the case.

For example, the substrate 11 may be directly joined to the first heat transfer part 22 in the region A1. Even in this case, the substrate 11 is joined to the first heat transfer part 22 in the region A1, and thus it is possible to suppress occurrence of a fracture or a crack of the substrate 11.

That is, it is preferable that the substrate 11 is directly joined to the first heat transfer part 22 in the region A1 or the substrate 11 is joined to the first heat transfer part 22 in the region A1 through a substance having heat conductivity higher than heat conductivity of air. In addition, it is more preferable that the substrate 11 is directly joined to the first heat transfer part 22 over the entirety of the region A2, or the substrate 11 is joined to the first heat transfer part 22 over the entirety of the region A2 through a substance having heat conductivity higher than heat conductivity of air.

In addition, in the first embodiment to the fourth embodiment as described above, description has been given of an example in which the protrusion 21a that is also a part of the second heat transfer part 21 is set as the heat transfer portion, but it is not necessary for the protrusion 21a to be formed integrally with the plate-shaped member 21b. That is, the protrusion 21a may be a protrusion separate from the second heat transfer part 21.

For example, the second heat transfer part 21 may be constructed by only the plate-shaped member 21b, and the protrusion separate from the second heat transfer part 21 may be provided between the plate-shaped member 21b of the second heat transfer part 21 and the first electrode 15. In this case, for example, the protrusion may be formed of a material different from that of the second heat transfer part 21, and thus it is possible to improve the degree of freedom in the selection of material.

In addition, in the first embodiment to the fourth embodiment, the cavity portion 20 that is an air layer having heat conductivity lower than heat conductivity of the protrusion 21a is formed between the protrusions 21a adjacent to each other in the first direction L1, but there is no limitation to this case.

For example, it is possible to employ a thermoelectric conversion device in which a low heat conduction material having heat conductivity lower than that of the protrusion 21a is set as a low heat conduction portion, and is formed on a lower surface side of the plate-shaped member 21b to substitute the cavity portion 20 that is an air layer. As the low heat conduction material, for example, aluminum oxide (Al₂O₃), polytetrafluoroethylene (PTFE), a polyimide resin, and the like can be used. Even in this case, it is possible to preferentially transfer heat received by the second heat transfer part 21 to the first electrode 15 through the protrusion 21a, and it is possible to transfer heat from the first electrode 15 to an end on the hot junction side of the thermoelectric conversion film (the first thermoelectric conversion film 12 and the second thermoelectric conversion film 13).

In addition, in the first embodiment to the fourth embodiment as described above, there is no limitation to the protrusion 21a as the heat transfer portion.

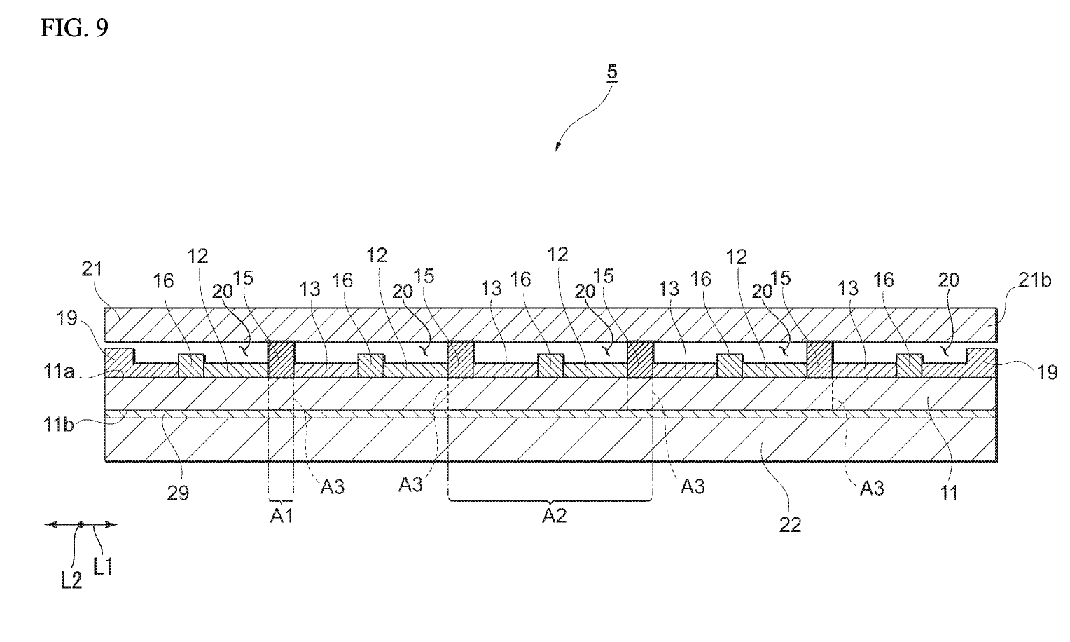

For example, as illustrated in FIG. 9, it is possible to employ a thermoelectric conversion device 5 in which the second heat transfer part 21 is constructed by only the plate-shaped member 21b, the first electrode 15 is made to protrude upward in comparison to the thermoelectric conversion film (the first thermoelectric conversion film 12 and the second thermoelectric conversion film 13), the second electrode 16, and the terminal 19, and the first electrode 15 is brought into contact with the lower surface of the plate-shaped member 21b.

In this case, it is preferable that the first electrode 15 is brought into contact with the lower surface of the plate-shaped member 21b in a state in which the plate-shaped member 21b and the first electrode 15 are electrically insulated from each other.

Even in the thermoelectric conversion device 5 configured as described above, it is possible to preferentially transfer heat received by the second heat transfer part 21 to the first electrode 15, and it is possible to transfer heat from the first electrode 15 to an end on the hot junction side of the thermoelectric conversion film (the first thermoelectric conversion film 12 and the second thermoelectric conversion film 13).

Accordingly, even in the case of the thermoelectric conversion device 5, it is possible to exhibit the same operational effect as in the thermoelectric conversion device 1 according to the first embodiment. In addition, in this case, the first electrode 15 can be allowed to function as a heat transfer portion.

Furthermore, as the heat transfer portion, various configurations can be employed as long as it is possible to perform heat transfer with a thermoelectric conversion film through the heat transfer portion in preference to heat transfer with the thermoelectric conversion film without through the heat transfer portion.

In addition, in the first embodiment to the fourth embodiment, description has been given of an example in which the second heat transfer part 21 is provided, but the second heat transfer part 21 is not an essential configuration and may not be provided.

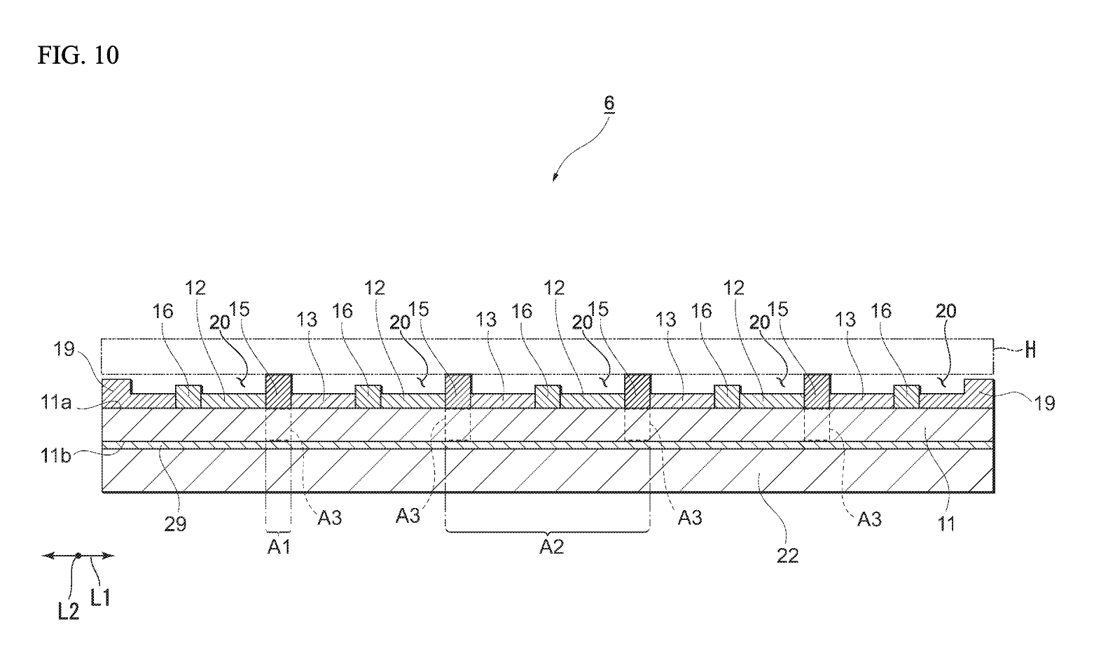

For example, as illustrated in FIG. 10, it is possible to employ a thermoelectric conversion device 6 having a configuration in which the second heat transfer part 21 in the first embodiment is omitted. Furthermore, in the aspect illustrated in FIG. 10, the same reference numerals will be given to the same constituent elements as in the first embodiment, and descriptions thereof will be omitted.

The thermoelectric conversion device 6 is different from the first embodiment in that the first electrode 15 is allowed to function as the heat transfer portion in addition to the configuration in which the second heat transfer part 21 is not provided. The other configurations are the same as those of the first embodiment.

In the thermoelectric conversion device 6, the first electrode 15 protrudes upward in comparison to the thermoelectric conversion film (the first thermoelectric conversion film 12 and the second thermoelectric conversion film 13), the second electrode 16, and the terminal 19. In addition, the first electrode 15 is in thermal contact with a heat source H. According to this, it is possible to preferentially transfer heat from the heat source H to an end on the hot junction side of the thermoelectric conversion film (the first thermoelectric conversion film 12 and the second thermoelectric conversion film 13) through the first electrode 15.

Accordingly, even in the thermoelectric conversion device 6 configured as described above, it is possible to exhibit the same operational effect as in the thermoelectric conversion device 1 according to the first embodiment. Particularly, since the second heat transfer part 21 is not provided, it is possible to make the entire thickness of the thermoelectric conversion device 6 smaller in comparison to the first embodiment, and thus it is easy to realize a reduction in thickness and compactification.

Furthermore, in FIG. 10, description has been given of an example of the thermoelectric conversion device 6 that is not provided with the second heat transfer part 21 on the basis of the embodiment 1, but it is possible to employ a configuration in which the second heat transfer part 21 is not provided in the other embodiments.

### INDUSTRIAL APPLICABILITY

According to the disclosure, it is possible to provide a thermoelectric conversion device in which a fracture or a crack of a substrate is less likely to occur. Accordingly, the disclosure has industrial applicability.
1, 2, 3, 4, 5, 6 Thermoelectric conversion device
11 Substrate
11a First surface
11b Second surface
12 First thermoelectric conversion film (thermoelectric conversion film)
13 Second thermoelectric conversion film (thermoelectric conversion film)
15 First electrode (heat transfer portion)
16 Second electrode
17 Third electrode
19 Terminal
20 Cavity portion (low heat conduction portion)
21 Second heat transfer part
21a Protrusion (heat transfer portion)
21b, 22b Plate-shaped member
22 First heat transfer part
22a Protrusion
29 Paste-like substance

1-6. (canceled)

7. A thermoelectric conversion device, comprising:
a substrate including a first surface and a second surface which are opposite to each other in a thickness direction;
at least one thermoelectric conversion film disposed on the first surface; and
a first heat transfer part disposed on a second surface side,
wherein the substrate is joined to the first heat transfer part in a movable state with respect to the first heat transfer part.

8. The thermoelectric conversion device according to claim 7,
wherein a paste-like substance is provided between the substrate and the first heat transfer part.

9. The thermoelectric conversion device according to claim 7, further comprising at least one heat transfer portion disposed on a first surface side and performing heat transfer with the thermoelectric conversion film,
wherein at least one low heat conduction portion having heat conductivity lower than heat conductivity of the heat transfer portion is provided in a portion that is adjacent to the heat transfer portion in an in-plane direction of the substrate.

10. The thermoelectric conversion device according to claim 9,
wherein the substrate is joined to the first heat transfer part in a region of the second surface which is opposite to the heat transfer portion in the thickness direction.

11. The thermoelectric conversion device according to claim 10,
wherein the at least one thermoelectric conversion film comprises a plurality of thermoelectric conversion films,
the at least one heat transfer portion comprises a plurality of heat transfer portions,
the at least one low heat conduction portion comprises a plurality of low heat conduction portions,
the thermoelectric conversion films and the heat transfer portions are formed at intervals in a first direction along the in-plane direction,
each of the low heat conduction portions is formed to be located between the heat transfer portions adjacent to each other in the first direction, and
the substrate is joined to the first heat transfer part over an entirety of a region of the second surface which is opposite to a region ranging from one heat transfer portion out of two of the heat transfer portions adjacent to each other in the first direction to the other heat transfer portion in the thickness direction.

12. The thermoelectric conversion device according to claim 9, further comprising:
a second heat transfer part that is disposed on the first surface side and has heat conductivity higher than heat conductivity of the low heat conduction portion,
wherein the second heat transfer part performs heat transfer with the thermoelectric conversion films through the heat transfer portion.

13. The thermoelectric conversion device according to claim 9,
wherein the low heat conduction portion is a cavity portion.

14. A thermoelectric conversion device, comprising:
a substrate including a first surface and a second surface which are opposite to each other in a thickness direction;
a plurality of thermoelectric conversion films disposed on the first surface;
a plurality of heat transfer portions disposed on a first surface side and performing heat transfer with the thermoelectric conversion films; and
a first heat transfer part disposed on a second surface side,
wherein a plurality of low heat conduction portions having heat conductivity lower than heat conductivity of the heat transfer portions is provided in portions that are adjacent to the heat transfer portions in an in-plane direction of the substrate,
the thermoelectric conversion films and the heat transfer portions are formed at intervals in a first direction along the in-plane direction,
each of the low heat conduction portions is formed to be located between the heat transfer portions adjacent to each other in the first direction, and
the substrate is joined to the first heat transfer part over an entirety of a region of the second surface which is opposite to a region ranging from one heat transfer portion out of two of the heat transfer portions adjacent to each other in the first direction to the other heat transfer portion in the thickness direction.

15. The thermoelectric conversion device according to claim 14,
wherein heat conductivity of the first heat transfer part is higher than heat conductivity of the substrate.

16. The thermoelectric conversion device according to claim 14,
wherein the first heat transfer part is made of metal.

17. The thermoelectric conversion device according to claim 14,
wherein the substrate is joined to the first heat transfer part in a movable state with respect to the first heat transfer part.

18. The thermoelectric conversion device according to claim 17,
wherein a paste-like substance is provided between the substrate and the first heat transfer part.

19. The thermoelectric conversion device according to claim 14, further comprising:
a second heat transfer part that is disposed on the first surface side and has heat conductivity higher than heat conductivity of the low heat conduction portions,
wherein the second heat transfer part performs heat transfer with the thermoelectric conversion films through the heat transfer portions.

20. The thermoelectric conversion device according to claim 14,
wherein the low heat conduction portions are cavity portions.
